(19) United States
(12) Patent Application Publication
(10) Pub. No.: US 2025/0102732 A1
(43) Pub. Date: Mar. 27, 2025

(54) LOW-COST SENSING SYSTEM BASED ON FUNCTIONALIZED FIBER AND TRANSIMPEDANCE AMPLIFIER CIRCUIT WITH WIRELESS INTERROGATION CAPABILITY

(71) Applicant: UNIVERSITY OF PITTSBURGH-OF THE COMMONWEALTH SYSTEM OF HIGHER EDUCATION, PITTSBURGH, PA (US)

(72) Inventors: PAUL R. OHODNICKI, JR., ALLISON PARK, PA (US); YANG-DUAN SU, PITTSBURGH, PA (US); NAGESWARA RAO LALAM, DRAVOSBURG, PA (US); JORDAN ATHAS, LISLE, IL (US); CARTER N. LEATHERMAN, PITTSBURGH, PA (US)

(73) Assignee: UNIVERSITY OF PITTSBURGH-OF THE COMMONWEALTH SYSTEM OF HIGHER EDUCATION, PITTSBURGH, PA (US)

(21) Appl. No.: 18/730,823

(22) PCT Filed: Feb. 2, 2023
(86) PCT No.: PCT/US2023/061823

§ 371 Date: Jul. 22, 2024

Related U.S. Application Data
(60) Provisional application No. 63/306,330, filed on Feb. 3, 2022.

(51) Int. Cl. G02B 6/12; H03F 3/08; H04B 10/67

(52) U.S. Cl. CPC G02B 6/12004; H03F 3/08; H04B 10/67; G02B 2006/12102; G02B 2006/12111; G02B 2006/12123; G02B 2006/12138

(57) ABSTRACT

A fiber optic based sensing system and method includes a. functionalized optical fiber based sensor including an engineered sensing layer, a light source structured to generate light and couple the light into an input of the functionalized optical fiber based sensor, and an interrogator including a photodetector coupled to the functionalized optical fiber based sensor to receive transmitted or reflected tight, a transimpedance amplifier (TIA) circuit coupled to an output of the photodetector, a controller coupled to an output of the TIA circuit, and a transmitter (e.g., a wired or wireless transmitter) coupled to the controller.

### CROSS-REFERENCE TO RELATED APPLICATIONS

This application claims priority under 35 U.S.C. § 119 (e) from U.S. provisional patent application No. 63/306,330, titled “Low-Cost Sensing System Based on Functionalized Fiber and Transimpedance Amplifier Circuit with Wireless Interrogation Capability” and filed on Feb. 3, 2022, the contents of which are incorporated herein by reference.

### FIELD OF THE INVENTION

The present invention pertains to sensing systems for sensing various parameters, (such as, without limitation, temperature, gas concentration, or magnetic field level) in, for example, an industrial/commercial or residential system/setting, and, in particular, to a sensing system that utilizes a functionalized optical fiber based sensor and a transimpedance amplifier circuit with wireless interrogation capability to measure one or more parameters of interest.

### BACKGROUND OF THE INVENTION

Temperature monitoring has been an indispensable part of both normal operation optimization and imminent failure detection of electric power equipment. In addition to thermal monitoring, analysis of gas phase chemistry within electrical assets (including above or within insulation oil, within battery cells, adjacent to insulation paper, etc.) can also provide an early indicator of asset health. For this reason, dissolved gas analysis sampling or real-time monitoring is commonly utilized for large power transformers today. Ultimately, monitoring of electrical parameters such as magnetic fields and electric fields is also of interest to allow for direct measurements of electrical power flow in the form of currents or stored charge within an asset or electrical system. Fiber optic sensors are well-known to overcome the challenges of conventional electrical sensors presented by compact, chemically-harsh, and electromagnetic interference conditions of electrical assets. These advantages of optical fibers enable internal measurements with high sensitivity with more accurate results.

Previously, fiber Bragg Grating (FBG) sensors and Fabry-Perot interferometers have been embedded in Li-ion cells to probe the internal temperature increase during the charging/discharging. Internal measurement lowers the uncertainties associated with estimation of battery internal states, hence avoiding battery module oversizing and maximizing the useful capacity of a single cell. Other than point temperature sensing, thermal mapping at a module level bas also been demonstrated with a quasi-distributed FBG network to identify anomalous hotspots for a possible cause of thermal runaway. However, the fabrication of FBG sensors requires expensive equipment such as an excimer laser or a CO2 laser, which results in a relatively high cost for these types of sensors.

In addition, optical interrogation system costs are substantial due to the need for fine wavelength resolution of the detectors and narrow-band high intensity light sources at tuned wavelengths. On the other hand, distributed fiber temperature sensors, such as Rayleigh backscattered based optical frequency-domain reflectometry (OFDR), has been deployed to monitor the internal temperature distribution of commercial power transformer. However, existing fiber-optic techniques for both distributed and quasi-distributed fiber sensors require a high cost of sensor fabrication and an expensive interrogation system, which leads to a huge economic burden that can make deployment prohibitive with the exception of very high value assets and systems. For example, the cost of these distributed/quasi-distributed interrogators typically ranges from $15,000 to $50,000. It is difficult to justify these costs for low and medium-voltage electrical assets, unless utility-scale energy systems are considered to support exceedingly large capital investment and spread the cost across numbers of spatially distributed sensing points, which is highly unlikely given economic and regulatory realities within the electrical power transmission and distribution system.

### SUMMARY OF THE INVENTION

In one embodiment, a sensing system is provided that includes a functionalized optical fiber based sensor including an engineered sensing layer, a light source structured to generate light and couple the light into an input of the functionalized optical fiber based sensor, and an interrogator including a photodetector coupled to the functionalized optical fiber based sensor to receive transmitted or reflected light, a transimpedance amplifier (TIA) circuit coupled to an output of the photodetector, a controller coupled to an output of the TIA circuit, and a transmitter, such as, without limitation a wireless transmitter, coupled to the controller.

In another embodiment, a fiber optic based sensing method is provided that includes generating incident light and coupling the incident light into an input of a functionalized optical fiber based sensor, the functionalized optical fiber based sensor including an engineered sensing layer, receiving transmitted light or reflected light in a photodetector coupled to the functionalized optical fiber based sensor, receiving an output of the photodetector in a TIA circuit, and generating and transmitting (e.g., wirelessly) a parameter signal based on and in response to an output of the TIA circuit, the parameter signal being indicative of a parameter being monitored by the functionalized optical fiber based sensor.

### BRIEF DESCRIPTION OF THE DRAWINGS

FIG. 1 is a schematic diagram of a fiber optic sensing system according to an exemplary embodiment of the disclosed concept;

FIGS. 2A-2C show the optical and temperature response of certain exemplary embodiment of the disclosed concept;

FIGS. 3A-3C are schematic diagrams of exemplary TIA circuits that may be employed in connection with the disclosed concept;

FIGS. 4A and 4B are schematic diagrams of exemplary energy harvesting circuits that may be employed in connection with the disclosed concept; and

FIGS. 5A and SB are schematic diagrams of alternative exemplary approaches for self-collimation of and LED and coupling to an optical fiber member that may be employed in connection with the disclosed concept.

### DETAILED DESCRIPTION

As used herein, the singular form of “a”, “an”, and “the” include plural references unless the context clearly dictates otherwise.

As used herein, the statement that two or more parts or components are “coupled” shall mean that the parts are joined or operate together either directly or indirectly, i.e., through one or more intermediate parts or components, so long as a link occurs.

As used herein, “directly coupled” means that two elements are directly in contact with each other.

As used herein, the term “number” shall mean one or an integer greater than one (i.e., a plurality).

As used herein, the term “controller” shall mean a programmable analog and/or digital device (including an associated memory part or portion) that can store, retrieve, execute and process data (e.g., software routines and/or information used by such routines), including, without limitation, a field programmable gate array (FPGA), a complex programmable logic device (CPLD), a programmable system on a chip (PSOC), an application specific integrated circuit (ASIC), a microprocessor, a microcontroller, a programmable logic controller, or any other suitable processing device or apparatus. The memory portion can be any one or more of a variety of types of internal and/or external storage media such as, without limitation, RAM, ROM, EPROM(s), EEPROM(s), FLASH, and the like that provide a storage register, i.e., a non-transitory machine readable medium, for data and program code storage such as in the fashion of an internal storage area of a computer, and can be volatile memory or nonvolatile memory.

As used herein, the term “engineered sensing layer” shall mean a layer of material that is coupled to an optical fiber and that has parameter (e.g., temperature, gas concentration, magnetic field level or some other external sensing parameter) dependent optical properties that causes the intensity level change of an optical fiber based sensor that includes the engineered sensing layer to change depending on and in response to the level of the parameter in question. Such engineered sensing layers may include, without limitation, layers made of a nanocomposite material. In addition, such sensing layers may include a localized surface plasmon resonance (LSPR) peak.

As used herein, the term “nanocomposite material” shall mean a multiphase solid material where one of the phases has at least one dimension of 100 nanometers (nm) or less, such as, without limitation, a bulk (e.g., oxide) matrix with a plurality of nanoparticles (e.g., Au nanoparticles) dispersed throughout.

As used herein, the term “nanoparticle” shall mean an object that behaves as a whole unit with respect to its transport and properties having a size (e.g., diameter or width) ranging from 1 to 100 μm.

Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

The disclosed concept will now be described, for purposes of explanation, in connection with numerous specific details in order to provide a thorough understanding of the disclosed concept. It will be evident, however, that the disclosed concept can be practiced without these specific details without departing from the spirit and scope of this innovation.

As described in detail herein, the disclosed concept provides a cost-effective fiber optic sensor and simplified design of an interrogation system employing same. The fiber sensor is, in the exemplary embodiment, coated with one or more engineered sensing layers, such as a layer made of a plasmonic nanocomposite thin film material(s). The fiber sensor is implemented in conjunction with a low-cost light source, such as a low-cost collimated LED, and is interrogated by a photodetector/transimpedance amplifier (TIA)/wireless communications circuit to measure the level of one or more parameters in question (such as, without limitation, temperature, gas concentration, or magnetic field level). As two examples of existing wireless communications circuits, both nRF24L01+ RF and LoRa RF chips/technologies (with ATmega328P microcontrollers) may be used as part of the wireless communications circuit. Of these two, LoRa RF has been proven to have increased range capability and wireless transmission stability in terms of overcoming obstacles with existing investigations to date.

The low-cost nature of the disclosed concept is, in the exemplary embodiment, enabled by a functionalized multimode silica fiber, commercially available electrical components-assembled circuits on printed circuit boards (PCB), and the nature of an optical intensity-based sensor without the need of high wavelength resolution spectrometers. Besides the cost advantage, the fiber and interrogation system of the disclosed concept is compact with the design of the PCB, and can therefore easily fit into commercial energy control systems such as battery management systems in electric vehicles or grid storage. The fiber sensor may also be configured in a reflection sensing geometry as a temperature probe for ease of installation in energy systems. Another advantage is the wireless communication between the interrogator and signal monitor allowed by wireless communication hardware, such as nRF24L01+ or LoRa RF modules with communication distance op to 3 miles, which can be ideal for remotely monitoring medium to high voltage transformers or utility-scale energy storage devices for safety considerations. This can also be extended to cloud-based sensor data communication and analytics, such as a LoRaWAN gateway as one example.

Lastly, as opposed to existing wavelength-modulated sensors relying on spectral wavelength shifts, a nanocomposite thin-film functionalized fiber sensor as used in the disclosed concept is featured by intensity changes in the characteristic localized surface plasmon resonance (LSPR) peak within the visible spectrum. The applications of interest ranges from low to high voltage inductors, resistors, and transformers under sinusoidal and square-wave excitations, and Li-ion batteries from cell to module-level at normal and abuse charging/discharging conditions. Although temperature sensing signals are shown for exemplary purposes, other parameters may also be monitored through appropriate selection of functional sensing layers including gas phase chemical species (e.g. H₂, CO, CO₂, C₂H₂, C₂H₄, O₂, etc.), magnetic and electric fields, and others.

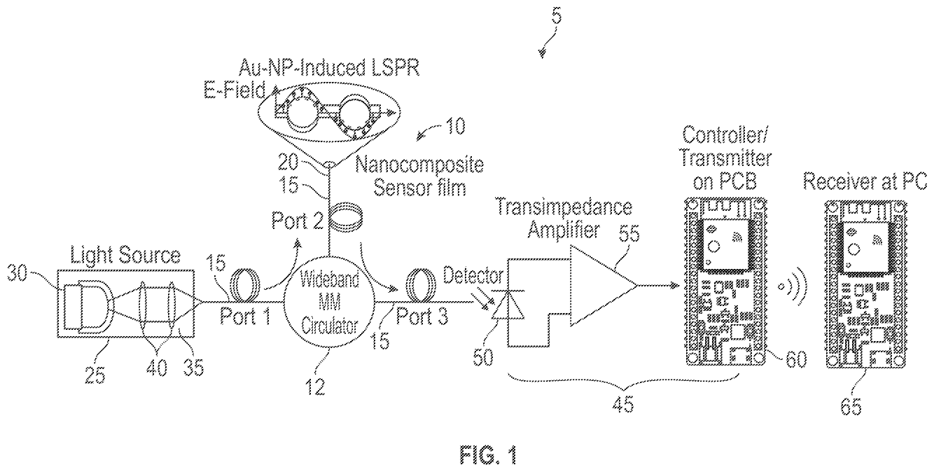

FIG. 1 is a schematic diagram of a fiber optic sensing system 5 according to an exemplary embodiment of the disclosed concept. As described in detail herein, sensing system 5 is, in the non-limiting exemplary embodiment, structured and configured to be deployed within a residential or commercial/industrial system, and once so deployed, measure a number of parameters of interest (such as temperature, gas concentration and/or magnetic field strength) and wirelessly transmit the parameter measurements to a monitoring computer system forming part of fiber optic sensing system 5. In the non-limiting exemplary embodiment shown in FIG. 1, fiber optic sensing system 5 is configured in a reflection sensing geometry. It will be appreciated, however, that this is meant to be exemplary only and that other sensing geometries (e.g., a transmission geometry) are also contemplated within the scope of the disclosed concept.

As seen in FIG. 1, fiber optic sensing system 5 includes a functionalized optical fiber based sensor 10. Functionalized optical fiber based sensor 10 includes an optical fiber member 15, such as multimode silica fiber having a core, and a wideband MM circulator 12 to enable the reflection geometry. An engineered sensing layer 20 is provided (e.g., by a suitable coating method) on an outer surface of at least a portion of optical fiber member 15. In the exemplary embodiment, engineered sensing layer 20 comprises a nanocomposite material. In one particular embodiment, engineered sensing layer 20 comprises a plasmonic nanocomposite material including a bulk matrix with a plurality of nanoparticles dispersed throughout. In the illustrated embodiment, the bulk, material is an oxide material and the nanoparticles are An nanoparticles, although other types of bulk and/or nanocomposite materials, such as other plasmonically active particles (e.g., Ag, Pd, Pt, alloys, core-shell, non-spherical, etc.), are contemplated within the scope of the disclosed concept. As described elsewhere herein, functionalized optical fiber based sensor 10 exhibits parameter (e.g., temperature, gas concentration, magnetic field level) dependent optical properties that cause the intensity level of the sensor to change depending on and in response to the level of the parameter in question.

Fiber optic sensing system 5 also includes a light source 25 that is coupled to a first end of functionalized optical fiber based sensor 10. Light source 25 is structured to generate light of a certain selected wavelength and direct that light into the first end of functionalized optical fiber based sensor 10. In the non-limiting exemplary embodiment, light source 25 includes a light emitting diode (LED) 30 that is coupled to a lens system 35 comprising one or more lenses 40 for collimation. In one particular exemplary embodiment (described and shown Elsmere herein), the one or more lenses 40 comprise a balls lens, such as a fused silica or polymer based ball lens. In addition, in one exemplary embodiment, LED 30 and lens system 35 are covered in a heat-shrink tube for packaging.

Fiber optic sensing system 5 further includes a wireless interrogator apparatus 45. Wireless interrogator apparatus 45 is structured and configured to measure the intensity of the light that is transmitted through functionalized optical fiber based sensor 10 and transmit such intensity information wirelessly to a remote destination, such as a remotely located computer system 65 (e.g., a PC). This will enable remotely located computer system 65 to monitor any shifts that occur in the intensity of functionalized optical fiber based sensor 10 that is caused by the parameter being measured. As seen in FIG. 1, in the exemplary embodiment, wireless interrogator apparatus 45 includes a photodiode 50 that is coupled to an output end of functionalized optical fiber based sensor 10, a transimpedance amplifier (TIA) circuit 55 coupled to the output of photodiode 50, and a controller/wireless transmission module 60 that is coupled to the output of TIA circuit 55. Photodiode 50 is structured and configured to receive light from the output end of functionalized optical fiber based sensor 10 and convert that light to a corresponding current. TIA circuit 55 is a current to voltage converter, typically implemented with one or more operational amplifiers, that is structured and configured to amplify the received current and convert that current into a usable voltage. The usable voltage values/signals are then provided to wireless controller/transmission module 60 for transmission to computer system 65 using control logic and one or more transceiver devices of wireless controller/transmission module 60.

According to one particular exemplary embodiment of the disclosed concept, wireless interrogator apparatus 45 comprises a photodiode, a TIA circuit, a microcontroller, a transmitter, a number of indicator LEDs, a battery connection and voltage regulators provided on a single printed circuit board (PCB). This embodiment thus provides a photodiode transimpedance amplifier circuit integrated with programmed wireless transceiver and microcontroller functionality, where the voltage output from the transimpedance amplifier is connected to an analog input pin of the microcontroller. A minimum threshold voltage is set for the indicator LED at one of the output pins to blink. This is to ensure the baseline intensity of the LED at the source end is interrogatable, meaning that it is “capable of being fiber sensor interrogated”. In the exemplary embodiment, the sensor interrogator should have a baseline measurement (the signal should indicate zero, and link to absolute temperature). For example, the temperature change ΔT(x)=T(x) abs−Tbase; where T(x) abs is the absolute temperature along the fiber and Tbase is the baseline temperature. An output pin of the microcontroller sends amplified voltage signals to the transmitter, which in turn communicates those signals wirelessly to computer system 65 to display real-time voltage variations using appropriate (e.g., Arduino IDE) programming commands.

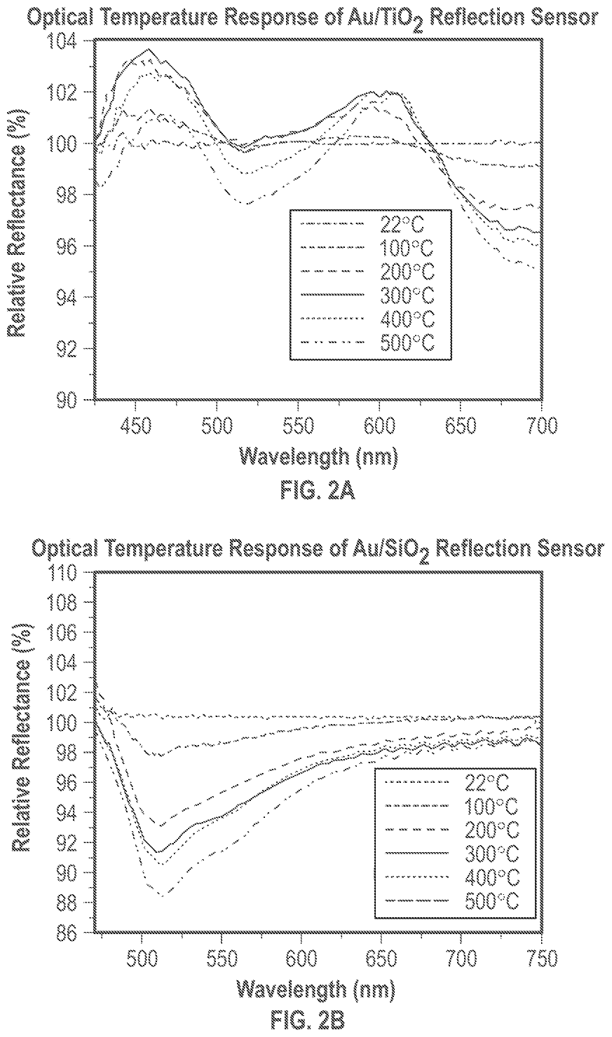

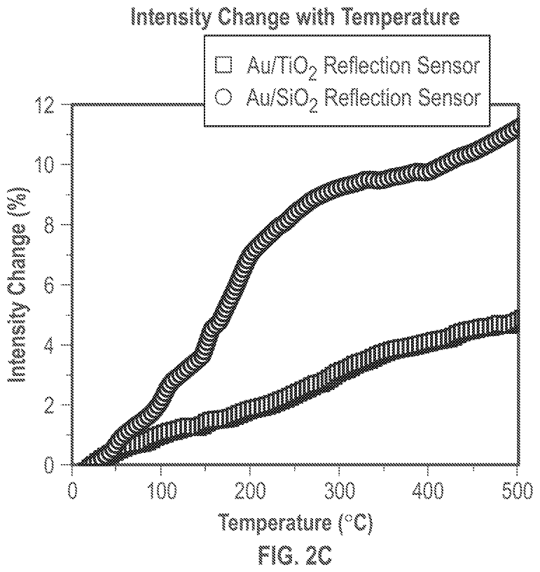

In one exemplary embodiment, engineered sensing layer 20 is in the form of an Au/TiO₂ layer having Au nanoparticles dispersed throughout a TiO₂ matrix. The optical temperature response of such an exemplary embodiment is shown in FIG. 2A. In another exemplary embodiment, engineered sensing layer 20 is in the form of an Au/SiO₂ layer having Au nanoparticles dispersed in a SiO₂ matrix. The optical temperature response of such an exemplary embodiment is shown in FIG. 2B. These embodiments make it possible to mitigate cross-sensitivity and discriminate multiple parameters with different spectral features when compared with wavelength-shift-based sensors. The response of these exemplary embodiments with temperature can be seen in FIG. 2C. Such nanocomposite material embodiments that include an oxide matrix with Au nanoparticles dispersed throughout can be made by standard physical vapor deposition methods followed by heat treatment of the coated fiber at a temperature ranging from 100-900° C., depending on the matrix of choice. The temperature-induced optical intensity response is due to the increase in resistivity of gold as the temperature increases. As a result, the damping frequency associated with the drift velocity of free electrons increases, which reduces the LSPR absorption peak and thus modifies the reflection of the sensing film. In theory, the position of the LSPR peak can be tuned by annealing temperature or Au concentrations, both of which changes the particle size of Au. The applications of interest ranges from low to high voltage inductors, resistors, and transformers under sinusoidal and square-wave excitations, and Li-ion batteries from cell to module-level at normal and abuse charging/discharging conditions. In addition to temperature sensing, the same sensing architecture can be applied to monitor alternative parameters including gas/chemical species (H₂, CO₂, CH₄, other vapors, etc.), humidity, magnetic fields, electric fields, and others if appropriate sensing layers are utilized. Multiparameter sensing is also possible by utilizing multiple sensing layers or even a single sensing layer, but with multiple wavelengths to be interrogated. This can be done by only modestly increasing the complexity of the sensor, such as increasing the number of photodiodes and applying multiple sources or filters to allow for wavelength discrimination. In some cases, the sensors can be combined with an analytics method of additional self-referencing hardware platform to allow for multiple wavelength discrimination and correction for light source drift or other sources of noise/errors.

As described above, in the exemplary embodiment, the wireless interrogator 45 includes a collimated LED (light source 25), a pigtailed photodiode (photodiode 50), a TIA circuit 55, a transmitter, and a receiver (with respective microcontrollers) (controller/wireless transmission module 60). When incident light from LED 30 propagates through optical fiber based sensor 10, the changes in reflected light intensity results in changes in the photocurrent generated by diode 50. The current is then picked up by TIA circuit 55 and converted and amplified into voltage outputs. The operation of TIA circuit 55 in photovoltaic mode eliminates the need for a reverse bias voltage and thus increases the signal-to-noise ratio by avoiding dark current. Both resistive and capacitive feedback topologies may be employed to control and stabilize the output by tuning the gain, signal-to-noise ratio (SNR) and bandwidth of the operational amplifier (op-amp).

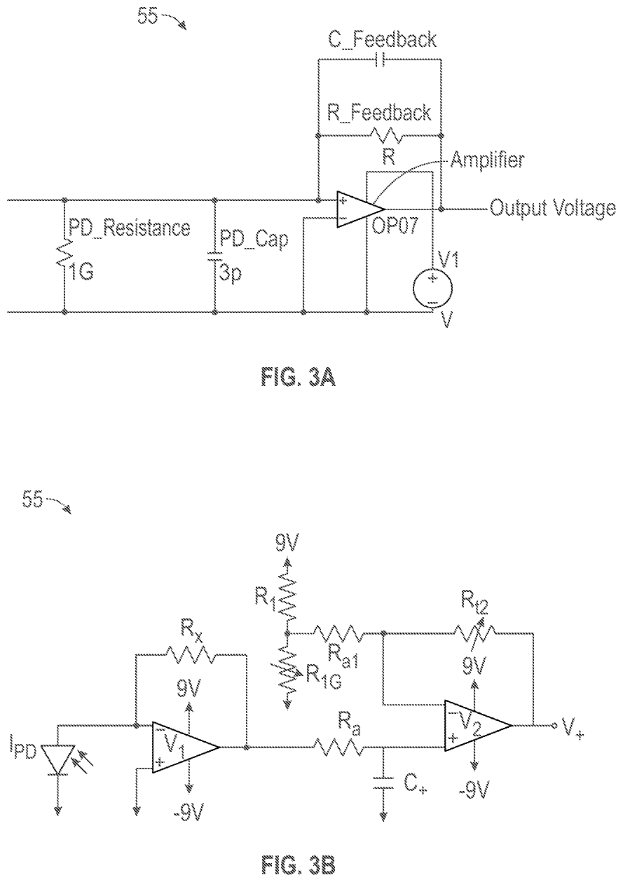

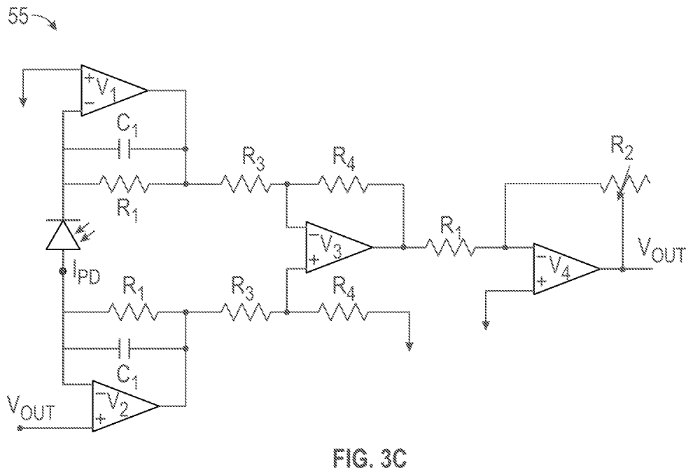

FIG. 3A is a schematic diagram of a basic TIA circuit 55 that may be employed in system 5 according to one exemplary embodiment, where the TIA gain is defined by the ratio between the max, difference of output voltage and max, difference of input photocurrent. As seen in FIG. 3A, TIA circuit 55 includes feedback resistor and compensation capacitor to control the gain. FIG. 3B is a schematic diagram of an alternative dual-stage TIA circuit 55 that may be employed in system 5 according to another exemplary embodiment. In the design of FIG. 3B, TIA circuit 55 is provided with high and low gain amplifiers that are used to control the DC offset, so that the minimum photocurrent can correspond to the minimum input voltage range of the analog-to-digital convertor (ADC) in the wireless module. A low-pass filter with a cut-off frequency defined by a resistor is included to capture low-frequency optical response from the sensor. FIG. 3C is a schematic diagram of a further alternative TIA circuit 55 according to still another exemplary embodiment. The design of FIG. 3C is a multi-amplifier design for higher SNR performance. For each of these exemplary designs, an output pin of the microcontroller sends amplified voltage signals to the transmitter, which communicates with the receiver at computer system 65, which is able to display real-time voltage variations using appropriate (e.g., Arduino IDE) programming commands. A number of additional modifications, enhancements, and improvements to the TIA. concepts illustrated here can also be envisioned for the purpose of tailoring the signal to noise ratio, minimizing noise, integrating multiple signals in a multiparameter sensor, and other methods and techniques.

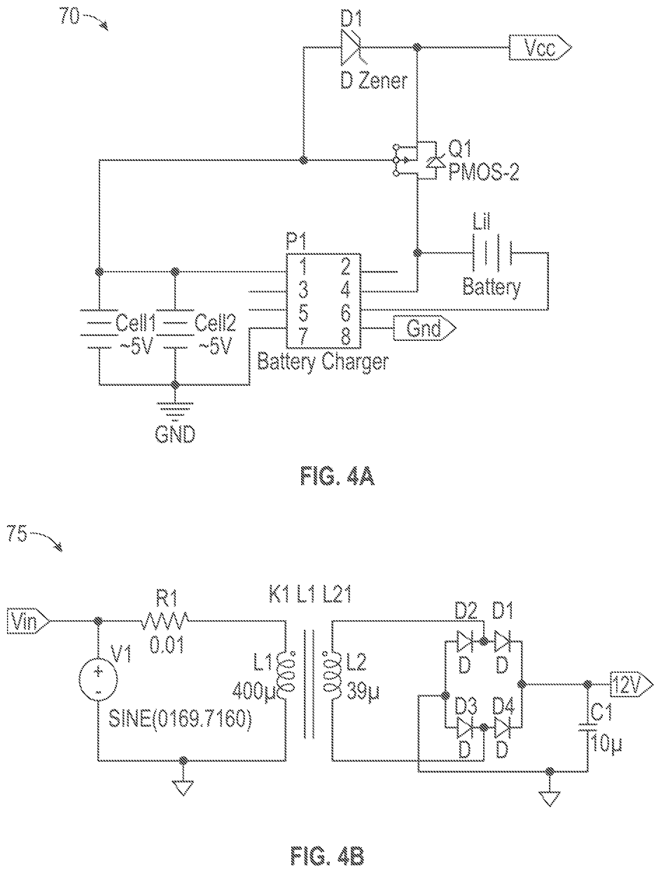

Moreover, in the exemplary embodiment, the disclosed concept provides energy harvesting for powering the components of fiber optic sensing system 5. In particular, two options for energy harvesting power sources have been investigated to power light source 25, TIA circuit 55, and controller/wireless transmission module 60. FIG. 4A is a schematic diagram of an energy harvesting circuit 70 according to one particular embodiment that harvests energy from sunlight. Energy harvesting circuit 70 may be operatively coupled to the components of FIG. 1 that require power. As seen in FIG. 4A, energy harvesting circuit 70 includes two photovoltaic (PV) cells integrated with Li-ion batteries, with control by a battery protection unit. The PV cells are put in series to maximize the voltage that can be supplied, with a current maximum of 8.8V with direct sunlight incident on both cells. A battery charging IC is included in the circuit design to safely charge and discharge the lithium ion battery. Lastly a zener diode and a PMOS transistor are used in a switching circuit that allows the PV cells to power TIA circuit 55 when they reach a certain voltage, and allows the battery to power the circuit if the sunlight incident on the cells is insufficient. FIG. 4B is a schematic diagram of an energy harvesting circuit 75 according to another particular embodiment that harvest energy from the electric equipment being monitored. Energy harvesting circuit 75 may be operatively coupled to the components of FIG. 1 that require power. Energy harvesting circuit 75 is a current transformer (CT) set that is designed to gain redundant power from the energy system being monitored by optical fiber based sensor 10. CTs are normally used to measure the current of a line by producing a current proportional to the turns of wire on the transformer. The induced current can then be analyzed to determine any disruptions in the current. In this case, however, the current can be harvested and regulated with the proposed CT circuit to power the system 5. Alternative powering techniques can instead utilize a standard battery-based powering circuit operatively coupled to the components of FIG. 1 that require power, although energy harvesting methods are preferred.

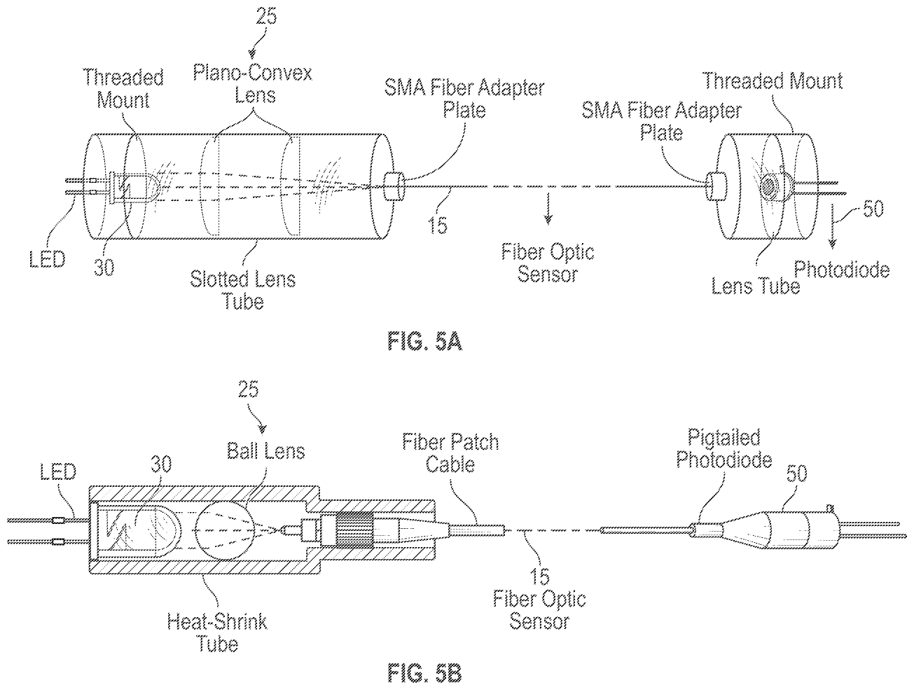

Furthermore, the disclosed concept provides two alternative exemplary approaches for self-collimation of LED 30 and coupling to optical fiber member 15. A first approach is shown in FIG. SA, and employs a threaded mount, plano-convex lenses, a slotted lens tube, and an SMA fiber adapter plate as part of light source 25 as shown. This first approach also employs an SMA fiber adapter plate, a lens tube and a threaded mount for coupling to photodiode 50. A second approach is shown in FIG. 5B, and employs a heat shrink tube, a ball lens and a fiber patch cable as shown.

The disclosed concept as described herein thus provides a number of novel features and advantages. For example, in case of LSPR based sensing layers, the wavelength tunability of the characteristic LSPR peak in the transmission spectrum of the proposed fiber sensor is unique and can therefore be potentially utilized for a simultaneous multi-parameter sensing. One possible method is by cascading different sensing materials with customized wavelength position of their respective LSPR peaks, and by monitoring the real-time intensity changes of the different peaks multiple parameters can be resolved. For gas and temperature sensing as an example: one segment of the sensor can be coated with temperature-sensitive material that is non-absorptive to the gas molecule of interest, while the other coated with highly-gas sensitive porous nanocomposite material. The temperature and gas concentration induced optical intensity responses can thus be discriminated. Data-driven approaches such as Principal Component Analysis (PCA) or Support Vector Machines (SVM) can also be implemented to discriminate the convoluted multiple parameters. In addition to LSPR based sensing layers, other types of sensing layers can also be considered with sufficiently large optical responses particularly if they are wavelength selective.

Furthermore, the wireless interrogation-to-monitoring feature is ideal for the practical implementation of fiber optic sensors in residential and utility-scale field testing. The resulting remote monitoring feature enables a distant signal communication of hundreds of meters to several kilometers. The extra feature of integration with cloud services such as the LoRaWAN enables sensing data from multiplexed fiber optic point sensors to be stored in cloud and analyzed in real-time. Alternative communication methods may be considered possible, including wireline communications and standard wired or even fiber optic-based communication methods.

In addition, energy harvesting using current transformers, solar photovoltaics, thermoelectrics, vibrational energy harvesting circuits, or other appropriate technologies to minimize needs for local battery energy storage can provide for a particularly attractive embodiment of the solution. The low power requirements and simple circuit interrogation hardware required enable such low-cost energy harvesting methods in practice.

Finally, the total fiber sensing system cost of the disclosed concept can lie below $500-$600, or even as low as $100 or less. Examples of system components include multimode silica fiber, materials cost associated with thin-film fabrication, TIA and power source circuit components (capacitors, resistors, op-amps, and voltage regulators), diode and LED, and wireless communication set-ups. The current estimated cost is at least 10-50 times lower than the existing fiber optic sensor and interrogator system cost used in a laboratory setting. The total cost can be further reduced to below ˜$100 with careful design and selection.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

What is claimed is:

1. A sensing system, comprising:
a functionalized optical fiber based sensor including an engineered sensing layer;
a light source structured to generate light and couple the light into an input of the functionalized optical fiber based sensor; and
an interrogator including a photodetector coupled to the functionalized optical fiber based sensor to receive transmitted or reflected light, a transimpedance amplifier (TIA) circuit coupled to an output of the photodetector, a controller coupled to an output of the TIA circuit, and a transmitter coupled to the controller for transmitting a parameter signal based on and in response to an output of the TIA circuit, the parameter signal being indicative of a parameter being monitored by the functionalized optical fiber based sensor.

2. The system according to claim 1, wherein the photodetector is a photodiode.

3. The system according to claim 1, wherein the light source comprises an LED coupled to a lens system.

4. The system according to claim 3, wherein the lens system comprises a ball lens.

5. The system according to claim 1, wherein the engineered sensing layer is comprised of a nanocomposite material.

6. The system according to claim 5, wherein the nanocomposite material comprises a matrix with nanoparticles dispersed throughout.

7. The system according to claim 6, wherein the matrix is an oxide matrix.

8. The system according to claim 7, wherein the nanoparticles are plasmonically active nanoparticles.

9. The system according to claim 7, wherein the nanoparticles are Au nanoparticles.

10. The system according to claim 1, wherein the photodetector, the TIA circuit, the controller, and the wireless transmitter are provided on a single printed circuit board.

11. The system according to claim 1, wherein a voltage output from the TIA circuit is connected to an analog input pin of the controller, where an output pin of the controller is structured and configured to provide digital amplified voltage signals based on the voltage output to the wireless transmitter, wherein the wireless transmitter is structured and configured to wirelessly transmit the digital amplified voltage signals.

12. The system according to claim 1, wherein the transmitter is a wireless transmitter.

13. The system according to claim 12, wherein the wireless transmitter is an nRF24L01+ RF transmitter or an LoRa RF transmitter.

14. The system according to claim 1, wherein the system is configured in a reflection sensing geometry and wherein the functionalized optical fiber based sensor includes a circulator.

15. The system according to claim 1, wherein in the TIA circuit a TIA gain is defined by a ratio between a maximum difference of an output voltage and maximum difference of an input photocurrent, and wherein the TIA circuit includes a feedback resistor and a compensation capacitor to control the TIA gain.

16. The system according to claim 1, wherein the TIA circuit includes a high gain amplified and a low gain amplifier for controlling a DC offset of the TIA circuit, and a low-pass filter with a cut-off frequency defined by a resistor for capturing a low-frequency optical response from the functionalized optical fiber based sensor.

17. The system according to claim 1, wherein the TIA circuit includes a plurality of operational amplifiers for providing improved signal to noise ratio (SNR) performance.

18. The system according to claim 1, further comprising an energy harvesting circuit for powering the light source and the interrogator.

19. The system according to claim 18, wherein the energy harvesting circuit includes a plurality of series connected photovoltaic (PV) cells integrated with a number of batteries and a battery charging integrated circuit, and a switching circuit structured and configured for allowing the PV cells to power the TIA circuit when the PV cells reach a certain voltage, the switching circuit including a Zener diode and a PMOS transistor.

20. The system according to claim 18, wherein the energy harvesting circuit comprises a current transformer (CT) set structured and configured for to gain redundant power from an energy system being monitored by the functionalized optical fiber based sensor.

21. The system according to claim 1, wherein the functionalized optical fiber based sensor includes a second engineered sensing layer, wherein the engineered sensing layer and the second engineering sensing layer have different wavelength positions of their respective LSPR peaks.

22. The system according to claim 1, wherein the engineered sensing layer is structured and configured to have a plurality of different LSPR peaks corresponding to different wavelength positions.

23. A fiber optic based sensing method, comprising:
generating incident light and coupling the incident light into an input of a functionalized optical fiber based sensor, the functionalized optical fiber based sensor including an engineered sensing layer;
receiving transmitted light or reflected light in a photodetector coupled to the functionalized optical fiber based sensor;
receiving an output of the photodetector in a TIA circuit; and
generating and transmitting a parameter signal based on and in response to an output of the TIA circuit, the parameter signal being indicative of a parameter being monitored by the functionalized optical fiber based sensor.

24. The method according to claim 23, where generating and transmitting the parameter signal comprises wirelessly transmitting the parameter signal.
